(19) United States
(12) Patent Application Publication
(10) Pub. No.: US 2024/0102168 A1
(43) Pub. Date: Mar. 28, 2024

(54) PLASMA COATING APPARATUS AND COATING METHOD

(71) Applicant: JIANGSU FAVORED NANOTECHNOLOGY CO., LTD., Wuxi (CN)

(72) Inventor: Jian ZONG, Wuxi (CN)

(73) Assignee: JIANGSU FAVORED NANOTECHNOLOGY CO., LTD., (omitted)

(21) Appl. No.: 18/263,563

(22) PCT Filed: Jan. 11, 2022
(86) PCT No.: PCT/CN2022/071151

§ 371 Date: Jul. 31, 2023

(30) Foreign Application Priority Data
Feb. 1, 2021 (CN) 202110139694.7

(51) Int. Cl. C23C 16/505; C23C 16/458; C23C 16/54

(52) U.S. Cl. CPC C23C 16/505; C23C 16/458; C23C 16/54

(57) ABSTRACT

Provided are a plasma coating apparatus and a coating method. The plasma coating apparatus uses radio frequency discharge, and a discharge coil can be arranged in the lengthwise direction of a coating cavity, so as to provide a plasma environment for a base material when the base material moves within the coating cavity in the lengthwise direction of the coating cavity.

### CROSS-REFERENCE TO RELATED APPLICATIONS

This application claims the benefit of priority to Chinese Patent Application No. 202110139694.7, filed with China National Intellectual Property Administration on Feb. 1, 2021, and entitled “PLASMA COATING APPARATUS AND COATING METHOD”, the entire disclosure of which is incorporated herein by reference.

### TECHNICAL FIELD

The present disclosure relates to the surface treatment field, and particularly, to a plasma coating apparatus and a coating method.

### BACKGROUND

Plasma reaction device is important processing equipment applied in thin film deposition, etching, and surface treatment processes. Based on different inductive coupling elements, it may be mainly divided into two types. One type is capacitive coupling plasma reaction device, which adopts a plate type capacitive coupling element to apply an excitation electric field with a driving frequency of 13.56 MHz to a reaction chamber to ionize a reactive gas into plasma. The drawbacks of a capacitive coupling plasma reaction device consist mainly in limitation thereof to capacitive coupling elements, and generated plasma with relatively low density and relatively high potential, and thus, making a surface of a substrate susceptible to bombardment by active particles. Therefore, applying a capacitive coupling plasma reaction device for coating may affect final quality of a coated product. The other type is inductive coupling plasma reaction device, which adopts an inductively coupled coil that is driven by a radio frequency power supply to apply an excitation magnetic field to a reaction chamber to ionize a reactive gas into plasma.

A traditional inductively coupled coil excites a magnetic field that is relatively strong in central part and relatively weak in edge part of the reaction chamber in the reaction device. As a result, the plasma has a density that is relatively high in the central part and relatively low in the edge part of the reaction chamber. If the volume of the reaction chamber increases with the size of the substrate to be processed, there is a significant azimuthal asymmetry in the plasma excited by a traditional inductively coupled coil, resulting in uneven plasma distribution in the reaction chamber and affecting uniformity of formed coating. In addition, in actual industrial production, the more substrates processed in a single operation, the higher the production efficiency. That is to say, what is needed in industrial production is a large volume of plasma reaction device with high production efficiency, which, however, may have an accompanying problem of an intensified phenomenon of uneven plasma density distribution.

Currently, a common method to address this issue is to design structure of the inductively coupled coil, to even the plasma distribution. For example, a design scheme for a coil structure proposed in Chinese Patent No. CN101409126A may be referred to. However, this type of coils often have complex structures, and complex coil designs may result in relatively great inductance values, thereby increasing efficiency of “electrostatic coupling” and hindering the entire coating process.

### SUMMARY

One advantage of the present disclosure is to provide a plasma coating apparatus and a coating method, wherein the plasma coating apparatus includes a coating cavity capable of being designed to be large enough to process a lot of substrates in a single operation.

Another advantage of the present disclosure is to provide a plasma coating apparatus and a coating method, wherein the coating cavity of the plasma coating apparatus is capable of being designed to be relatively long, so that a loading device loaded with a substrate is capable of moving along the length direction of the coating cavity, so that the entire plasma coating apparatus is capable of being used for a continuous operation.

Still another advantage of the present disclosure is to provide a plasma coating apparatus and a coating method, wherein the plasma coating apparatus is provided with at least one discharge coil, which does not need to be designed as a complex structure and is capable of being arranged along the length direction of the coating chamber, so that the plasma in the coating chamber is capable of being rather evenly distributed.

Yet another advantage of the present disclosure is to provide a plasma coating apparatus and a coating method, wherein the plasma coating apparatus is provided with two or more discharge coils that are arranged around the coating cavity to provide a relatively uniform magnetic field around the substrate located in the coating cavity, so that the coating chamber is capable of being designed to be relatively large.

Still yet another advantage of the present disclosure is to provide a plasma coating apparatus and a coating method, wherein the plasma coating apparatus is provided with one discharge coil capable of being arranged around the coating cavity to provide a relatively uniform magnetic field around the substrate located in the coating cavity, so that the coating chamber is capable of being designed to be relatively large.

According to one aspect of the present disclosure, the present disclosure provides a plasma coating apparatus adapted for coating on a surface of a substrate, wherein the plasma coating apparatus includes:
a coating chamber having a coating cavity;
a loading device, wherein the substrate is adapted to be loaded onto the loading device, and the loading device is configured to be movable with the substrate in the coating cavity along the length direction of the coating cavity; and
a radio frequency discharge device including at least two discharge coils and at least one radio frequency power supply, wherein each of the discharge coils is conductively connected to one of the radio frequency power supply, and the discharge coils are arranged along the length direction of the coating chamber, so that when the substrate is loaded onto the loading device and moves in the coating cavity along the length direction of the coating cavity, the discharge coils connected conductively to the radio frequency power supply discharge to the substrate from one side of the substrate, to provide a plasma environment.

According to an embodiment of the present disclosure, the coating chamber includes a coating top wall, a coating bottom wall, and a coating side wall, wherein the coating top wall and the coating bottom wall are provided oppositely, the coating side wall extends between the coating top wall and the coating bottom wall, the coating bottom wall is adapted to be arranged towards the ground, and the loading device is provided to be movable along the length direction of the coating side wall, the at least two discharge coils are arranged around a motion trajectory of the loading device.

According to an embodiment of the present disclosure, the coating chamber includes a coating top wall, a coating bottom wall, and a coating side wall, wherein the coating top wall and the coating bottom wall are provided oppositely, the coating side wall extends between the coating top wall and the coating bottom wall, the coating bottom wall is adapted to be arranged towards the ground, and the loading device is provided to be movable along the length direction of the coating bottom wall, the at least two discharge coils are arranged around a motion trajectory of the loading device.

According to an embodiment of the present disclosure, the discharge coils are arranged inside or outside the coating chamber.

According to an embodiment of the present disclosure, the discharge coils are designed as planar structures, and are provided as spiral structures with several loops formed by outward rotation from a starting point in the middle position.

According to an embodiment of the present disclosure, the discharge coils include a first coil part and a second coil part, wherein the first coil part and the second coil part are respectively provided as spiral planar structures with several loops formed by outward rotation from a starting point in the middle position, and the first coil part is connected in series to the second coil part.

According to an embodiment of the present disclosure, the plasma coating apparatus further includes at least one mounting shell, wherein the mounting shell is provided between the coating cavity and the discharge coils and protrudes outward to form a cup shaped structure, and wherein the discharge coils are wound around the mounting shell.

According to an embodiment of the present disclosure, the plasma coating apparatus further includes a recipiency shell which is connected to the coating chamber and protrudes from the coating side wall, and a recipiency cavity which is communicated with the coating cavity of the coating chamber, wherein the discharge coils are provided on the recipiency shell.

According to an embodiment of the present disclosure, the plasma coating apparatus has a feed port, wherein the mounting shell has a mounting shell top wall and a mounting shell side wall which surround to form a mounting cavity, the feed port is provided on the mounting shell top wall, and the discharge coils are wound onto the mounting shell side wall.

According to an embodiment of the present disclosure, the plasma coating apparatus further includes a recipiency shell which is connected to the coating chamber and protrudes from the coating side wall, and a recipiency cavity which is communicated with the coating cavity of the coating chamber, and the mounting shell side wall of the mounting shell extends between the recipiency shell and the mounting shell top wall.

According to an embodiment of the present disclosure, the loading device includes a carrier and a moving unit, wherein the carrier is provided on the moving unit, so that the moving unit drives the carrier to move when moving, and wherein the coating apparatus further includes an impulsing power source, the carrier is conductively connected to the impulsing power source, so that at least a part of the carrier serves as an electrode for the impulsing power source.

According to another aspect of the present disclosure, the present disclosure provides a plasma coating apparatus, which includes;
a coating chamber having a coating cavity;
a loading device, wherein a substrate is adapted to be loaded onto the loading device, and the loading device is configured to be movable with the substrate in the coating cavity along the length direction of the coating cavity; and
a radio frequency discharge device including at least one discharge coil and at least one radio frequency power supply, wherein each of the discharge coil is conductively connected to one of the radio frequency power supply, and the discharge coil is arranged along the length direction of the coating chamber and around a motion trajectory of the loading device, so that when the substrate is loaded onto the loading device and moves in the coating cavity along the length direction of the coating cavity, the discharge coil connected conductively to the radio frequency power supply discharges to the substrate from one side of the substrate, to provide a plasma environment.

According to an embodiment of the present disclosure, the plasma coating apparatus further includes a recipiency shell which is connected to and protrudes from the coating chamber; and a recipiency cavity which is communicated with the coating cavity of the coating chamber, and the discharge coil is provided on the recipiency shell.

According to an embodiment of the present disclosure, the plasma coating apparatus further includes a bracket and an impulsing power source, wherein the bracket is arranged in the coating cavity of the coating chamber and conductively connected to the impulsing power source, so that at least a part of the bracket serves as an electrode for the impulsing power source.

According to still another aspect of the present disclosure, the present disclosure provides a coating method which includes:
providing a plasma environment for a substrate that is loaded onto a loading device and driven by the loading device to move in the coating chamber along the length direction of the coating chamber by means of at least one discharge coil arranged in a coating chamber of a coating apparatus, wherein the discharge coil is conductively connected to a radio frequency power supply; and
forming a coating on a surface of the substrate.

According to an embodiment of the present disclosure, in the above method, the number of the discharge coil is at least two, and at least one of the discharge coils is configured to cooperate with the other discharge coil in operation, so that the coating chamber provides a uniform plasma environment around the substrate.

According to an embodiment of the present disclosure, in the above method, the discharge coil surrounds a motion trajectory of the substrate.

According to an embodiment of the present disclosure, in the above method, the substrate is placed on a bracket, at least a part of the bracket is conductively connected to an impulsing power source, and coating is conducted under the combined action of the radio frequency power supply and the impulsing power source.

According to an embodiment of the present disclosure, in the above method, the substrate is placed on a bracket, and the bracket is provided to be rotatable to drive the substrate to rotate in the coating chamber, so that the plasma distributes evenly in the coating chamber.

### BRIEF DESCRIPTION OF THE DRAWINGS

FIG. 1A is a schematic view of a plasma coating apparatus according to a preferred embodiment of the present disclosure.

FIG. 1B is a schematic view of the plasma coating apparatus according to the above preferred embodiment of the present disclosure.

FIG. 2 is a schematic view of a plasma coating apparatus according to another preferred embodiment of the present disclosure.

FIG. 3 is a schematic view of a plasma coating apparatus according to another preferred embodiment of the present disclosure.

FIG. 4 is a schematic view of a plasma coating apparatus according to another preferred embodiment of the present disclosure.

FIG. 5 is a schematic view of a plasma coating apparatus according to another preferred embodiment of the present disclosure.

FIG. 6A is a schematic view of a plasma coating apparatus according to another preferred embodiment of the present disclosure.

FIG. 6B is a schematic view of a discharge coil according to a preferred embodiment of the present disclosure.

FIG. 6C is a schematic partial view of a plasma coating apparatus according to another preferred embodiment of the present disclosure.

### DETAILED DESCRIPTION

The following description serves to disclose the present disclosure, in order to enable one skilled in the art to realize the present disclosure. Preferred embodiments in the following description are given by way of example only, and other obvious variations will occur to those skilled in the art. The basic principles of the present disclosure defined in the following description may be applied to other embodiments, variations, modifications, equivalents, and other technical solutions without departing from the spirit and scope of the present disclosure.

It should be appreciated by those skilled in the art that, in the context of the present disclosure, the orientation or positional relationships indicated by the terms “longitudinal”, “transverse”. “upper”, “lower”, “front”, “back”, “left”, “right”, “vertical”, “horizontal”, “top”, “bottom”, “inner”, “outer”, etc. are based on those illustrated in the figures. In addition, these terms are merely for convenience in describing the present disclosure and to simplify the description, rather than to indicate or imply that the apparatus or element referred to must have a particular orientation or be constructed and operated in a particular orientation, and thus the above terms should not be construed as limiting the present disclosure.

It should be understood that, the term “a” or “an” should be interpreted as “at least one” or “one or more”, that is, in one embodiment, the number of an element may be one, and in another embodiment, the number of the element may be plural, and the term “a” or “an” should not be construed as a limitation on the number.

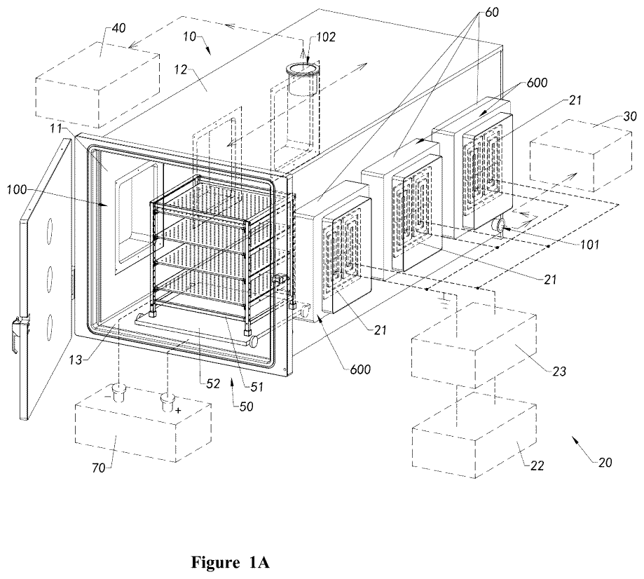

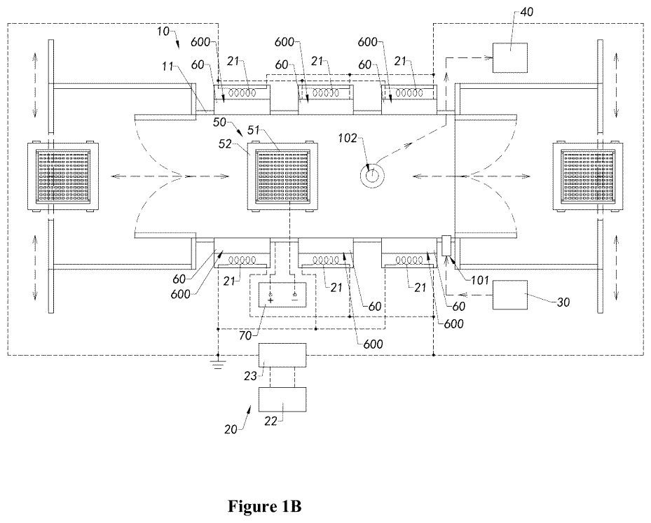

Referring to FIGS. 1A and 1B, which illustrate a plasma coating apparatus according to a preferred embodiment of the present disclosure. The plasma coating apparatus is used for chemically depositing a coating on a surface of a substrate through the Plasma Enhanced Chemical Vapor Deposition (PECVD) method, to improve surface properties of the substrate. The substrate may be glass, plastics, inorganic materials, or other materials with a surface to be coated or improved. The surface properties improved by the coating are exemplarily, but not limited to, hydrophobic and oleophobic properties, corrosion resistance property, rigidity, wear resistance property, and drop resistance property. The substrate may be implemented as electronic equipment, such as smart phones, tablet personal computers, electronic readers, wearable devices, televisions, and computer displays. The plasma refers to a hybrid state of electrons, positive and negative ions, excited atoms, molecules and free radicals.

Specifically, the plasma coating apparatus includes a coating chamber 10, a radio frequency discharge device 20, a feeding device 30, an air extractor 40, and at least one loading device 50. The coating chamber 10 has a coating cavity 100 in which a substrate may be placed to be deposited to form a coating. The radio frequency discharge device 20 is capable of providing an excitation magnetic field to the coating cavity 100, to ionize a reactive gas in the coating cavity 100 into plasma, which is then deposited onto a surface of the substrate to form the coating. The feeding device 30 is conductively connected to the coating chamber 10 through at least one feed port 101, to feed towards the coating chamber 10. The air extractor 40 is conductively connected to the coating chamber 10 through at least one outlet 102, to control and maintain the vacuum degree of the coating cavity 100 within an expected range, in order to facilitate formation of the coating. The loading device 50 is used for loading the substrate, and provided to be movable and able to move within the coating cavity 100 of the coating chamber 10.

The loading device 50 may include a carrier 51 and a moving unit 52. The carrier 51 is provided on the moving unit 52, so that the moving unit 52 may drive the carrier 51 to move while moving. The moving unit 52 may be a track, a wheel, or another movable device. The moving unit 52 may be an active moving device or a passive moving device.

It should be understood that, the raw material may be in a gaseous or non-gaseous state, and may ultimately be transferred in a gaseous state to the coating cavity 100 of the coating chamber 10 after passing through the feeding device 30.

The radio frequency discharge device 20 includes at least two discharge coils 21 and at least one radio frequency power supply 22. Each of the discharge coils 21 is conductively connected to the radio frequency power supply 22, which may be either one discharge coil 21 that is conductively connected to one radio frequency power supply 22, or different discharge coils 21 that are conductively connected to the same radio frequency power supply 22.

The number of the discharge coils 21 may be two or more. As a result, when the number of samples to be processed in the coating chamber 10 is great, the coating chamber 10 may be designed to have a relatively large volume, and the discharge coils 21 may be arranged to meet the coating requirements of the coating chamber 10 with a relatively large volume.

Furthermore, in this embodiment, the coating chamber 10 is designed to have a relatively long length, so that the coating chamber 10 is capable of coating a large number of substrates simultaneously.

Specifically, the coating chamber 10 includes a coating side wall 11, a coating top wall 12, and a coating bottom wall 13. The coating side wall 11 extends between the coating top wall 12 and the coating bottom wall 13. The coating side wall 11, the coating top wall 12, and the coating bottom wall 13 surround to form the coating cavity 100. The shapes and positions of the coating side wall 11, the coating top wall 12, and the coating bottom wall 13 determine the shape of the coating chamber 10. In this embodiment, the shape of the coating chamber 10 does not constitute a limitation, and may be implemented as a rectangular structure, a cylindrical structure, or even a spherical structure.

The coating top wall 12 and the coating bottom wall 13 may be provided to be relatively long, so that the entire coating chamber 10 has a relatively long length. The loading device 50 is provided on the coating bottom wall 13 of the coating chamber 10, and capable of moving along the length direction of the coating bottom wall 13. Certainly, it should be understood that, depending on the providing manner, the loading device 50 may also be suspended from the coating side wall 11 or the coating top wall 12 of the coating chamber 10.

When the loading device 50 moves along the length direction in the coating cavity 100, the discharge coils 21 of the radio frequency discharge device 20 is still capable of providing a relatively uniform magnetic field for the moving loading device 50, so that the substrate loaded on the moving loading device 50 may be coated. Certainly, it should be understood that, the loading device 50 may also be statically placed in the coating cavity 100 of the coating chamber 10.

In this embodiment, it is preferred that the loading device 50 is movable and has a number of more than one, and may be accommodated in the coating chamber 10 (a loading device 50 is illustrated in the figures). The loading device 50 enters the coating cavity 100 from one side of the coating chamber 10, and then passes through the coating cavity 100 along the length direction thereof to another side of the coating chamber 10, during which, the coating process may be completed. The operator may achieve the above goal by controlling the reaction environment in the coating chamber 10 and the movement speed of the loading device 50. Based on the sizes of the loading device 50 and of the coating cavity 100 of the coating chamber 10, the loading device 50 may be placed one after another into the coating chamber 10 from one end thereof, and then the loading device 50 that completes coating at another end of the coating chamber 10 may be taken out one after another.

It should be understood that, the two ends of the coating chamber 10 may be respectively provided in a closed device, so that the entire environment of the coating cavity 100 of the coating chamber 10 may be maintained when the coating chamber 10 is opened, so that the substrate being coated may continue to be coated, as shown in FIG. 1B. In other words, the taking out and placing into of the substrate(s) at both ends of the coating cavity 100 do not affect the coating of other substrates within the coating cavity 100.

The discharge coils 21 of the radio frequency discharge device 20 is arranged in the coating chamber 10, and may be adapted to the length direction of the coating chamber 10, to provide a relatively uniform magnetic field for the substrate on the loading device 50.

Specifically, in this embodiment, the discharge coils 21 of the radio frequency discharge device 20 are arranged on one side of the coated side wall 11. More specifically, the discharge coils 21 are arranged on the coating side wall 11 and outside the coating cavity 100.

The number of the discharge coils 21 is two, three, or more, illustrating with six as an example. In this embodiment, the coating bottom wall 13 of the coating chamber 10 is provided to may face the ground, and at least a part of the coating top wall 12, the coating bottom wall 13, and the coating side wall 11 are provided to be relatively long, so that the loading device 50 may move with the substrate along the length direction of the coating bottom wall 13. The coating chamber 10 has an axis. The axis passes through two opposite parts of the coating side wall 11 of the coating chamber 10. The coating top wall 12 and the coating bottom wall 13 are arranged around the axis. Two of the discharge coils 21 are arranged around the axis, and may be arranged on one side of the coating side wall 11. The other four discharge coils 21 are also respectively arranged in pairs around the axis and along the length direction of the coating chamber 10, so that the discharge coils 21 may continuously provide a magnetic field for the substrate when the loading device 50 moves forward.

From another perspective, the loading device 50 may move along a motion trajectory within the coating chamber 10, and at least two of the discharge coils may be arranged around the motion trajectory of the loading device 50, so that the plasma distribution is relatively uniform within the coating chamber 10 that is designed to be relatively large.

Furthermore, two discharge coils 21 located on the same layer are symmetrically arranged, and may be located on two opposite parts of the coating side wall 11. For example, the angle formed by the distances from two adjacent discharge coils 21 to the axis is 180°. For the coating cavity 100 of the coating chamber 10, the two discharge coils 21 are uniformly arranged therearound, so that the plasma may be uniformly arranged in the coating cavity 100 when the substrate is placed in the coating cavity 100 of the coating chamber 10 for processing. Preferably, the coating chamber 10 may also be provided as a symmetrical structure, which is either axially or centrally symmetrical, with the axis as a reference.

Through the above means, the uniformity of plasma distribution in the plasma coating apparatus is depressedly dependent on the structure of the discharge coils 21 themselves. That is to say, the plasma distribution in the plasma coating apparatus may be more uniform, by arranging the positions of a plurality of the discharge coils 21 relative to the coating chamber 10, without complex design for the structures of the discharge coils 21.

It should be understood that in this embodiment, the six discharge coils 21 may be arranged in three layers. In fact, the arrangement manners of the discharge coils 21 may be diverse, such as, for example, not necessarily being arranged in the same layer, but may be staggered.

It should be understood that, the coating chamber 10 may be an asymmetric structure. The plurality of discharge coils 21 may also be designed to be asymmetric. The discharge coils 21 may be arranged in a specific manner based on the structure of the coating chamber 10. In other words, the arrangement of the discharge coils 21 is not limited to a symmetrical design. In fact, the arrangement of the discharge coils 21 is matched with the concentrations of plasma at various positions of the coating chamber 10.

Exemplarily, when the coating chamber 10 is provided with one of the discharge coils 21, the staff found that the substrates produced by the plasma coating apparatus vary in quality, and thicknesses of the substrates at the central position are relatively thick, while those at the edge position are relatively thin. Therefore, another discharge coil 21 may be arranged to attempt to improve this phenomenon. However, it is not required that the latter discharge coil 21 and the former discharge coil should be symmetrically arranged.

Furthermore, it should be understood that, when a plurality of discharge coils 21 are arranged in the same coating chamber 10, it is not necessarily required that each of the discharge coils 21 has the same specification. For example, when the coating chamber 10 is provided with two larger discharge coils 21 symmetrically arranged, the staff found that the substrates produced by the plasma coating apparatus vary in quality, and thicknesses of the substrates located near the discharge coils 21 are relatively thick, while thicknesses of the substrates away from the discharge coils 21, that is, between the two discharge coils 21, are relatively thin. Then, the discharge coil(s) 21 may be additionally arranged between the two discharge coils 21, and may have specification(s) selected as relatively small coil(s), to assist the two foregoing discharge coils 21.

Furthermore, it should be understood that, the arrangement of two or more discharge coils 21 enables to expand the size of the coating chamber 10 to accommodate more substrates. In this embodiment, the coating chamber 10 may be provided as a horizontal structure that actually has a relatively long length, and the loading device 50 is capable of moving horizontally. In another embodiment of the present disclosure, the coating chamber 10 is provided as a vertical structure that actually has a relatively high height, and the loading device 50 is capable of moving upwards, and the loading device 50 may be transported one after another to the coating chamber 10, so that the entire coating process may be continuous. Certainly, it should be understood that based on actual production needs, the actual structure of the coating chamber 10 and the movement direction of the loading device 50 may be arranged according to the needs.

Furthermore, in this embodiment, the number of the radio frequency power supply 22 is implemented as one, and different discharge coils 21 may be connected in series with each other. In other embodiments of the present disclosure, the number of the radio frequency power supply 22 may also be two or more, and different discharge coils 21 are connected to different radio frequency power supplies 22, that is, the operation of each of the discharge coils 21 may be independent. The goal of uniform plasma distribution within the coating chamber 10 may be achieved by controlling different radio frequency powers of the discharge coils 21.

Returning to the example of symmetrical arrangement in this embodiment, the discharge coils 21 are arranged outside the coating chamber 10, and the radio frequency power supply 22 is also arranged outside the coating chamber 10. The radio frequency discharge device 20 may further include at least one match 23 used to connect the discharge coils 21 and the radio frequency power supply 22. The discharge coil(s) 21 may form a loop through the match 23 and the radio frequency power supply 22, wherein the match 23 may play a regulating role, so that the power of the radio frequency power supply 22 may be transmitted to both ends of the discharge coil(s) 21 to the maximum extent possible. A certain amount of radio frequency current may be generated in the discharge coil(s) 21, and a certain amplitude of voltage may be generated at both ends of the discharge coil(s) 21 simultaneously. The radio frequency current surrounding the discharge coil(s) 21 excites and generates a radio frequency magnetic field in the space where the discharge coil(s) 21 is(are) located, causing magnetic flux to be generated in the coating chamber 10. Based on Faraday law of electromagnetic induction, the radio frequency magnetic flux generated by the discharge coils 21 of the radio frequency discharge device 20 will induce and generate a radio frequency electric field, which will accelerate the movement of electrons in the plasma, making them constantly collide with and ionize neutral gas molecules, thereby coupling the radio frequency energy in the induction coils to the ionized gas and maintaining the plasma discharge.

Furthermore, the plasma coating apparatus includes a recipiency shell 60. The recipiency shell 60 is provided on a dielectric window of the coating side wall 11 of the coating chamber 10. The discharge coils 21 may be installed in the recipiency shell 60. At least a part of the recipiency shell 60 is provided for the magnetic field generated by the discharge coils 21 to pass through, and has material that may be but is not limited to ceramics or quartz. The discharge coils 21 may be designed as planar structures or as spatial structures. The recipiency shell 60 may has a recipiency cavity 600 formed therein, which is provided protrusively on the coating chamber 10 and communicated with the coating cavity 100. The discharge coils 21 may be placed in a flat part formed by the recipiency shell 60.

In this embodiment, the discharge coils 21 are implemented as planar structures, so that the discharge coils 21 have relatively large discharge areas towards the coating cavity 100, which is conducive to uniform discharge. It should be understood that, the plurality of discharge coils 21 may be arranged around the axis, and one discharge coil 21 may occupy one side of the coating side wall 11. Alternatively, several of the discharge coils 21 are arranged on the same side of the coating side wall 11 along the axial direction. For example, when the coating chamber 10 is a hexahedron structure, one of the four sides may be arranged with two of the discharge coils 21 in the upper and lower directions, and the other opposite side may also be arranged with two of the discharge coils 21 in the upper and lower directions.

Furthermore, the plasma coating apparatus includes an impulsing power source 70, which is arranged outside the coating chamber 10, and may work with the radio frequency power supply 22 together to provide a suitable plasma environment for the coating chamber 10. It is remarkable that, the plasma coating apparatus may complete coating in a low temperature environment of 30 to 50 Celsius degrees.

According to an embodiment of the present disclosure, the combined action of a radio frequency electric field and a pulsed electric field is adopted to assist in completing the plasma enhanced chemical vapor deposition process. According to some embodiments, both radio frequency and high-voltage pulses act simultaneously on the deposition process. During the combined action of radio frequency and high-voltage pulses, low-power radio frequency discharge is used to maintain the plasma environment, suppress arc discharge during high-voltage discharge, and thereby improve efficiency of chemical deposition.

Taking the deposition of DLC coating as an example, radio frequency may make the entire coating process in a plasma environment by discharging on an inert gas and a reactive gas raw material that is in a high-energy state. The function of pulse high voltage is to generate a strong electric field by the impulsing power source 70 during the discharge process. Active species in a high-energy state are accelerated to deposit on the surface of the substrate by the strong electric field, to form an amorphous carbon network structure. It is conducive to the free relaxation of the amorphous carbon network structure of the thin coating deposited on the surface of the substrate that the pulsed electric field is in a non-discharge state. Under the thermodynamic effect, the carbon structure transforms into a stable phase of bent graphene sheet structure, and is embedded in the amorphous carbon network, to form a transparent graphene-like structure. That is to say, the combination of radio frequency electric field and variable pulsed electric field enables the coating to be quickly and stably deposited on the surface of the substrate.

Furthermore, the carrier 51 may be conductively connected to the impulsing power source 70 to serve as an electrode thereof. In this embodiment, at least a part of the carrier 51 serves as the cathode of the impulsing power source 70, while the coating chamber 10 serves as the anode of the impulsing power source 70, and the carrier 51 and the coating chamber 10 are insulated from each other. The impulsing power source 70 may apply a bias voltage towards the carrier 51, and is capable of independently regulating the ion energy incident on the surface of the substrate by controlling the impulsing power source 70 that is conductive with the carrier 51.

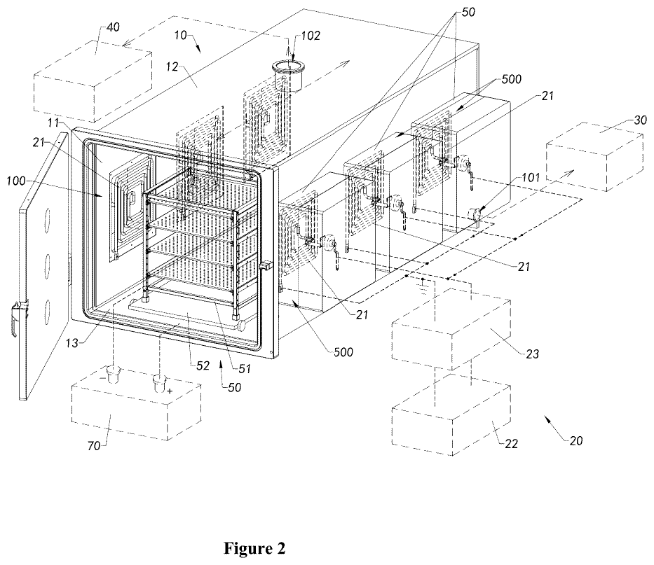

Referring to FIG. 2, which illustrates a plasma coating apparatus according to another preferred embodiment of the present disclosure.

In this embodiment, the plasma coating apparatus includes the coating chamber 10, the radio frequency discharge device 20, the feeding device 30, and the air extractor 40.

The radio frequency discharge device 20 includes at least two discharge coils 21, at least one radio frequency power supply 22, and at least one match 23. The discharge coils may be conductively connected to the radio frequency power supply 22 via the match 23.

In this embodiment, the discharge coils 21 are arranged inside the coating chamber 10. In the previous embodiment, the discharge coils 21 are arranged outside the coating chamber 10. Although dielectric materials such as quartz or ceramics have a certain effect on suppressing ion bombardment on the discharge coils 21 themselves from ions, they also affect coupling efficiency of radio frequency power. In this embodiment, by arranging the discharge coils 21 inside the coating chamber 10, the way in which dielectric materials are used to separate the discharge coils 21 and the plasma inside the coating chamber 10 is changed, which is beneficial for providing coupling efficiency of radio frequency power, and thereby improving the density of plasma.

Certainly, it should be understood that, the discharge coils 21 arranged inside the coating chamber 10 may also be provided with a dielectric material, so as to reduce the bombardment effect of the plasma inside the coating chamber 10 on the discharge coils 21 themselves.

In this embodiment, the discharge coils 21 are arranged to balance the plasma concentration in the coating chamber 10. It should be understood that, the discharge coils 21 may be arranged in a targeted manner based on different purposes. For example, the discharge coils 21 may be arranged based on the expectation of plasma balance at various positions of the entire coating chamber 10 of the plasma coating apparatus, or the expectation of plasma balance at specific positions of the coating chamber 10 of the plasma coating apparatus, which does not require that the plasma distribution in the entire coating chamber 10 be uniform. For example, if the user intends coating a small batch of substrates in the coating chamber 10 with a relatively large volume, they may choose to arrange these substrates in a middle area of the coating chamber 10, and the arrangement of the discharge coils 21 only needs to meet the balance of plasma distribution in this middle area.

An optional approach is to arrange two or more discharge coils 21 symmetrically, to achieve balanced plasma distribution in the coating chamber 10. The discharge coils 21 may be arranged axially or centrally symmetrically around the axis. Certainly, it should be understood that, the discharge coils 21 may also be arranged asymmetrically, and the specification of each of the discharge coils 21 may be different, referring to the description in the previous embodiment.

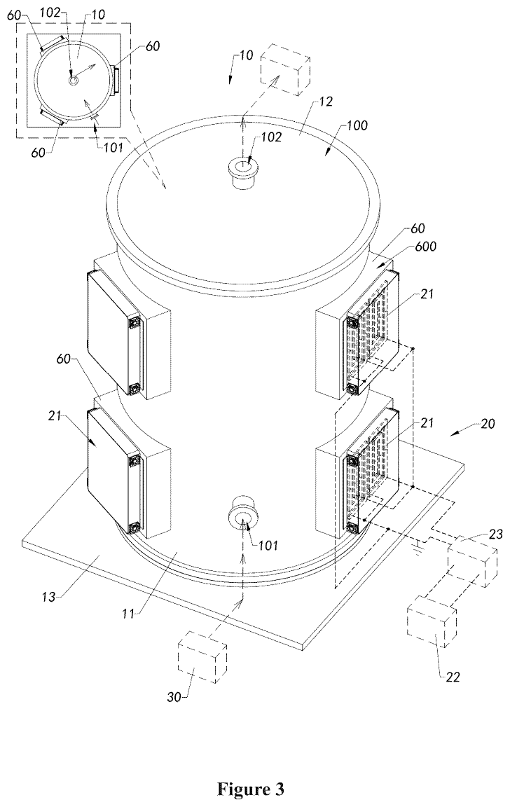

Referring to FIG. 3, which illustrates a plasma coating apparatus according to another preferred embodiment of the present disclosure.

This embodiment differs from the above embodiments mainly in the structure of the coating chamber 10 and the arrangement of the discharge coils 21.

In this embodiment, the coating side wall 11 of the coating chamber 10 is provided to be relatively long. The loading device 50 is provided to be movable along the coating side wall 11. The discharge coils 21 are arranged on the relatively long coating side wall 11 to provide a plasma environment for the substrate during the movement of the loading device 50.

According to some embodiments, the coating chamber 10 may accommodate two, three, or more loading devices 50. The loading device 50 may enter the coating cavity 100 one after another from the bottom of the coating chamber 10. And then, the substrates that has undergone the coating may leave the coating cavity 100 one after another from the top of the coating chamber 10. It should be understood that, during the process of the loading device 50 entering or leaving the coating chamber 10, the coating cavity 100 of the coating chamber 10 may remain closed, to allow the substrate being coated to continue to be coated normally. Similarly, closed devices may be provided at both ends of the loading device 50, to provide a buffer space for the entry and exit of the loading device 50. The loading device 50 that enters the coating chamber 10 may first be entered into the closed device, at which point the closed device and the coating cavity 100 of the coating chamber 10 remain isolated. And then, the closed device is communicated with the coating cavity 100, so that the loading device 50 may directly proceed to the coating cavity 100 of the coating chamber 10.

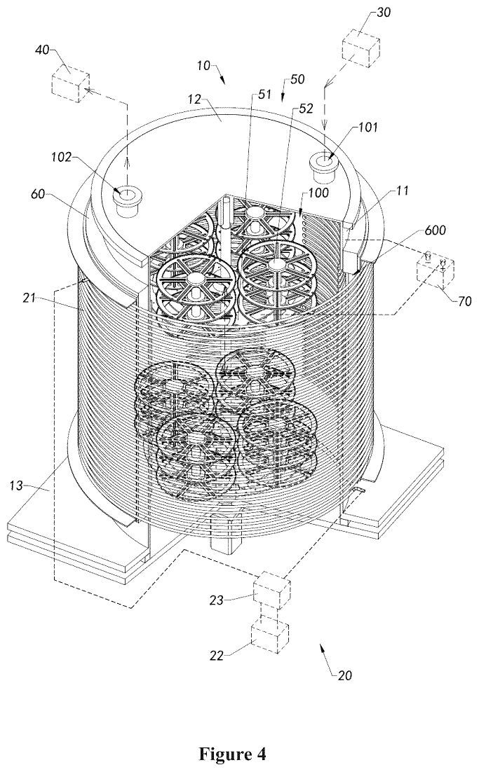

Referring to FIG. 4, which illustrates a plasma coating apparatus according to another preferred embodiment of the present disclosure.

In this embodiment, the plasma coating apparatus includes the coating chamber 10, the radio frequency discharge device 20, the feeding device 30, and the air extractor 40.

The radio frequency discharge device 20 includes at least one discharge coil 21, at least one radio frequency power supply 22, and at least one match 23. The discharge coil 21 may be conductively connected to the radio frequency power supply 22 via the match 23.

In this embodiment, the number of the discharge coil 21 may be one, two, or more. Taking the number of discharge coils 21 provided as one for an example. Specifically, in this embodiment, the discharge coil 21 is wound around the coating chamber 10. The coating chamber 10 has the coating side wall 11, the coating top wall 12, and the coating bottom wall 13. The coating side wall 11 is provided to be relatively long. The entire coating chamber 10 may be designed as a vertical device with a relatively high height. The loading device 50 may move along the height direction. The moving unit 52 of the loading device 50 may be arranged as a movable lifting structure.

The axis of the coating chamber 10 passes through the coating top wall 12 and the coating bottom wall 13. The discharge coil 21 is arranged around the axis of the coating chamber 10. Specifically, the discharge coil 21 is wound around the coating side wall 11 of the coating chamber 10, so that when a substrate is placed in the coating chamber 10 and supported on the coating bottom wall 13, the discharge coil 21 is capable of discharging around the substrate.

The specification, such as size and denseness, of the discharge coil 21 may be adaptively adjusted to even the plasma concentration within the coating chamber 10. For example, if the plasma concentration on the left side of the coating chamber 10 is relatively high, the number of coils wound by the discharge coil 21 on the coating side wall 11 on the left side of the coating chamber 10 may be reduced, or the discharge coil 21 corresponding to the coating side wall 11 on the left side may be replaced with a finer specification, or the denseness of the discharge coil 21 on the right side of the coating chamber 10 may be increased, so as to increase the density of the plasma on the right side of the coating chamber 10.

It should be understood that, the number of the discharge coil 21 may be two, one of which may surround the coating side wall 11, and the other of which may be arranged around the coating side wall 11 or at a certain position on the coating side wall 11 to cooperate with the previous surrounding discharge coil 21, in order to balance the plasma concentration in the coating chamber 10.

It should be understood that, the discharge coil 21 may also be arranged around when the coating chamber 10 is a structure extending horizontally.

Furthermore, the plasma coating apparatus includes a recipiency shell 60. The recipiency shell 60 is provided on a dielectric window of the coating side wall 11 of the coating chamber 10. The discharge coil 21 may be installed on the recipiency shell 60. At least a part of the recipiency shell 60 is provided for the magnetic field generated by the discharge coil 21 to pass through, and has material that may be but is not limited to ceramics or quartz. It should be understood that, the recipiency shell 60 may be formed by at least a part of the coating side wall 11, or may be provided to be independent of the coating side wall 11.

It should be understood that, when the number of discharge coil 21 exceeds one, different discharge coils 21 may be connected in series and connected to the same radio frequency power supply 22, or alternatively, different discharge coils 21 may be independent of each other and connected to different radio frequency power supplies 22, so that different discharge coils 21 may operate based on different radio frequency powers.

Furthermore, in this embodiment, the carrier 51 is rotatably mounted on the moving unit 52 to move relative to the coating chamber 10. The carrier 51 has a rotation axis that passes through the coating top wall 12 and the coating bottom wall 13 of the coating chamber 10. The carrier 51 may rotate around the rotation axis. Certainly, it should be understood that, the relative motion of the carrier 51 to the coating chamber 10 is not limited to rotation. By the movement of the carrier 51 relative to the coating chamber 10, the plasma in the coating chamber 10 may be driven to make the plasma concentration at various positions of the coating chamber 10 tend to be uniform.

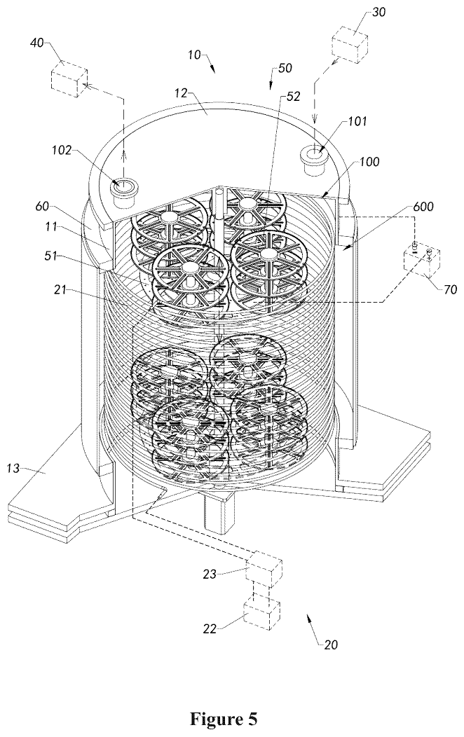

Referring to FIG. 5, which illustrates a plasma coating apparatus according to another preferred embodiment of the present disclosure.

In this embodiment, the plasma coating apparatus includes the coating chamber 10, the radio frequency discharge device 20, the feeding device 30, and the air extractor 40.

The radio frequency discharge device 20 includes at least one discharge coil 21, at least one radio frequency power supply 22, and at least one match 23. The discharge coil 21 may be conductively connected to the radio frequency power supply 22 via the match 23.

In this embodiment, the number of discharge coil 21 may be one, two, or more. Taking the number of the discharge coil 21 provided to be one as an example. The difference from the above embodiments is that in this embodiment, the discharge coil 21 may be arranged inside the coating chamber 10 and around along the inner side of the coating side wall 11 of the coating chamber 10, to leave as much space as possible for the substrate to be placed in the coating chamber 10.

Certainly, it should be understood that, when the number of discharge coil 21 exceeds one, one of the discharge coils 21 may be placed inside the coating chamber 10, and another one of the discharge coils 21 may be placed outside the coating chamber 10. The discharge coils 21 inside and outside the coating chamber 10 may cooperate in synergy.

In addition, the discharge coil(s) 21 arranged around may cooperate with the discharge coil(s) 21 arranged at a specific position, whether inside or outside the coating chamber 10.

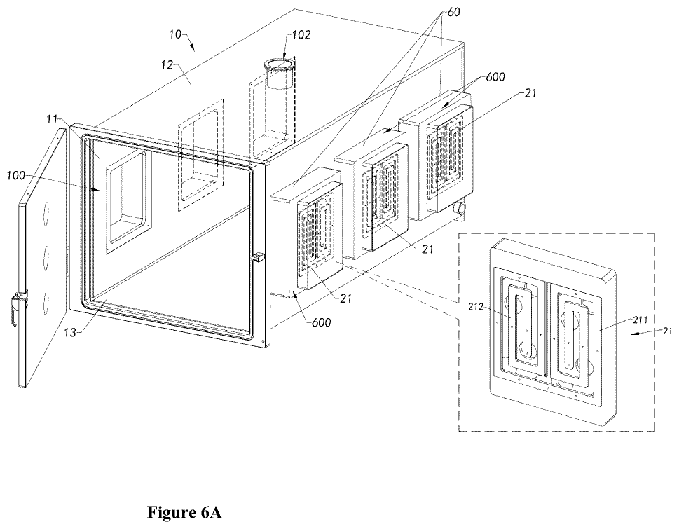

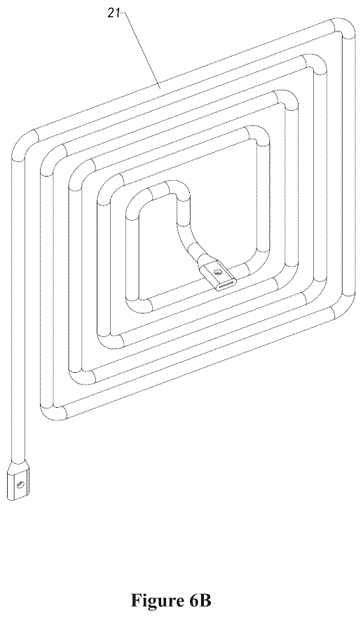

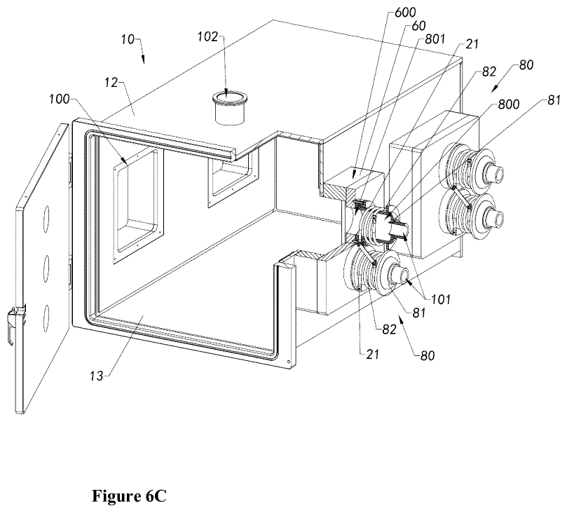

Referring to FIGS. 6A to 6C, which illustrate the discharge coils 21 according to the above preferred embodiment of the present disclosure.

As shown in FIG. 6A, the discharge coils 21 are designed as double “rectangular-ambulatory-plane” structures. The discharge coils 21 include a first coil part 211 and a second coil part 212 which maintain a predetermined distance. Moreover, the first coil part 211 is connected in series with the second coil part 212. The first coil part 211 and the second coil part 212 are designed as “rectangular-ambulatory-plane” structures, respectively. The discharge coils 21 may be arranged outside or inside the coating chamber 10. It should be understood that, the discharge coils 21 may be provided on one side of the coating side wall 11 of the coating chamber 10, and maintained at a certain distance from the coating side wall 11. Alternatively, the discharge coils 21 may be arranged directly on the coating side wall 11, and may be insulated therefrom.

If the discharge coils 21 are arranged outside the coating chamber 10, they may be installed on the recipiency shell 60 to allow magnetic flux to pass through the recipiency shell 60 and enter the coating cavity 100 of the coating chamber 10. In this embodiment, the recipiency shell 60 may be a planar structure. The first coil part 211 and second coil part 212 of the discharge coils 21 are provided as matching planar structures, and may be arranged independently on the recipiency shell 60, respectively.

As shown in FIG. 6B, the discharge coil 21 is designed as a single “rectangular-ambulatory-plane” structure. The discharge coil 21 may be provided as a “rectangular-ambulatory-plane” structure formed by outward and continuous spiral rotation of a central point. It should be understood that, when each turn of the discharge coil 21 has a rectangular shape, a “rectangular-ambulatory-plane” structure is formed. Those skilled in the art should understand that, the shape of each turn of the discharge coil 21 may be triangular or circular.

As shown in FIG. 6C, the discharge coils 21 are designed as spatial structures. Specifically, the plasma coating apparatus further includes a mounting shell 80. The mounting shell 80 is provided on the recipiency shell 60 and the two are communicated with each other. The mounting shell 80 is communicated with the coating cavity 100 of the coating chamber 10 via the recipiency shell 60. The mounting shell 80 and the recipiency shell 60 may be integrated or separated. The discharge coils 21 may be installed on the mounting shell 80 which is arranged in a cup shaped structure. The mounting shell 80 includes a mounting shell top wall 81, a mounting shell side wall 82, and a mounting port 801. The mounting port 801 is communicated with the coating cavity 100. The discharge coils 21 are wound around the mounting shell side wall 82 of the mounting shell 80.

In this embodiment, the mounting shell 80 is designed as a cylindrical structure. It should be understood that, the mounting shell 80 may also be designed as a prism or a structure with other shapes. The discharge coils 21 surround mounting cavities 800 of the mounting shells 80. The mounting cavities 800 may have the same size at various positions, so that the discharge coils 21 surround to form cylindrical shapes that are uniform up-and-down. The mounting cavities 800 may have different sizes at various positions. For example, the discharge coils 21 may surround to form structures which are large on top and small at bottom, or small on top and large at bottom. Here, the top refers to the end close to the coating cavity 100, and the bottom refers to the end far away from the coating cavity 100.

Furthermore, the plasma coating apparatus has two feed ports 101. The feeding device 30 is conductively connected to the feed ports 101, and feeds the coating cavity 100 of the coating chamber 10 via the feed ports 101. In this embodiment, the feed ports 101 are arranged on the mounting shells 80, and are located at intermediate positions on the mounting shell top walls 81. The raw materials that have entered the mounting cavities 800 of the mounting shells 80 via the feed ports 101 may be plasmonized under the effect of the magnetic field generated by the discharge coils 21 uniformly arranged therearound.

Furthermore, the discharge coils 21 may be installed at intermediate positions on the coating side walls 11 of the coating chamber 10 via the mounting shells 80.

It should be understood by those skilled in the art that, the embodiments of the present disclosure shown in the above description and the accompanying drawings are only examples and do not limit the present disclosure. The objects of the present disclosure have been fully and effectively achieved. The functional and structural principles of the present disclosure have been shown and explained in the embodiments, and any variations or modifications of the embodiments of the present disclosure are possible without departing from the principles.

1. A plasma coating apparatus adapted for coating on a surface of a substrate, comprising:
a coating chamber having a coating cavity;
a loading device, wherein the substrate is adapted to be loaded onto the loading device, and the loading device is configured to be movable with the substrate in the coating cavity along the length direction of the coating cavity; and
a radio frequency discharge device comprising at least two discharge coils and at least one radio frequency power supply, wherein each of the discharge coils is conductively connected to one of the radio frequency power supply, and the discharge coils are arranged along the length direction of the coating chamber, so that when the substrate is loaded onto the loading device and moves in the coating cavity along the length direction of the coating cavity, the discharge coils connected conductively to the radio frequency power supply discharge to the substrate from one side of the substrate, to provide a plasma environment.

2. The plasma coating apparatus according to claim 1, wherein the coating chamber comprises a coating top wall, a coating bottom wall, and a coating side wall, wherein the coating top wall and the coating bottom wall are provided oppositely, the coating side wall extends between the coating top wall and the coating bottom wall, the coating bottom wall is adapted to be arranged towards the ground, and the loading device is provided to be movable along the length direction of the coating side wall, the at least two discharge coils are arranged around a motion trajectory of the loading device.

3. The plasma coating apparatus according to claim 1, wherein the coating chamber comprises a coating top wall, a coating bottom wall, and a coating side wall, wherein the coating top wall and the coating bottom wall are provided oppositely, the coating side wall extends between the coating top wall and the coating bottom wall, the coating bottom wall is adapted to be arranged towards the ground, and the loading device is provided to be movable along the length direction of the coating bottom wall, the at least two discharge coils are arranged around a motion trajectory of the loading device.

4. The plasma coating apparatus according to claim 1, wherein the discharge coils are arranged inside or outside the coating chamber.

5. The plasma coating apparatus according to claim 1, wherein the discharge coils are designed as planar structures, and are provided as spiral structures with several loops formed by outward rotation from a starting point in the middle position.

6. The plasma coating apparatus according to claim 1, wherein the discharge coils comprise a first coil part and a second coil part, wherein the first coil part and the second coil part are respectively provided as spiral planar structures with several loops formed by outward rotation from a starting point in the middle position, and the first coil part is connected in series to the second coil part.

7. The plasma coating apparatus according to claim 1, further comprising at least one mounting shell, wherein the mounting shell is provided between the coating cavity and the discharge coils and protrudes outward to form a cup shaped structure, and wherein the discharge coils are wound around the mounting shell.

8. The plasma coating apparatus according to claim 6, further comprising a recipiency shell which is connected to and protrudes from the coating chamber; and a recipiency cavity which is communicated with the coating cavity of the coating chamber, wherein the discharge coils are provided on the recipiency shell.

9. The plasma coating apparatus according to claim 7, having a feed port, wherein the mounting shell has a mounting shell top wall and a mounting shell side wall which surround to form a mounting cavity, the feed port is provided on the mounting shell top wall, and the discharge coils are wound onto the mounting shell side wall.

10. The plasma coating apparatus according to claim 9, further comprising a recipiency shell which is connected to and protrudes from the coating chamber; and a recipiency cavity which is communicated with the coating cavity of the coating chamber, and the mounting shell side wall of the mounting shell extends between the recipiency shell and the mounting shell top wall.

11. The plasma coating apparatus according to claim 1, wherein the loading device comprises a carrier and a moving unit, wherein the carrier is provided on the moving unit, so that the moving unit drives the carrier to move when moving, and wherein the plasma coating apparatus further comprises an impulsing power source, the carrier is conductively connected to the impulsing power source, so that at least a part of the carrier serves as an electrode for the impulsing power source.

12. A plasma coating apparatus, comprising:
a coating chamber having a coating cavity;
a loading device, wherein a substrate is adapted to be loaded onto the loading device, and the loading device is configured to be movable with the substrate in the coating cavity along the length direction of the coating cavity; and
a radio frequency discharge device comprising at least one discharge coil and at least one radio frequency power supply, wherein each of the discharge coil is conductively connected to one of the radio frequency power supply, and the discharge coil is arranged along the length direction of the coating chamber and around a motion trajectory of the loading device, so that when the substrate is loaded onto the loading device and moves in the coating cavity along the length direction of the coating cavity, the discharge coil connected conductively to the radio frequency power supply discharges to the substrate from one side of the substrate, to provide a plasma environment.

13. The plasma coating apparatus according to claim 12, further comprising a recipiency shell which is connected to and protrudes from the coating chamber; and a recipiency cavity which is communicated with the coating cavity of the coating chamber, and the discharge coil is provided on the recipiency shell.

14. The plasma coating apparatus according to claim 12, further comprising a bracket and an impulsing power source, wherein the bracket is arranged in the coating cavity of the coating chamber and conductively connected to the impulsing power source, so that at least a part of the bracket serves as an electrode for the impulsing power source.

15. A coating method, comprising:
providing a plasma environment for a substrate that is loaded onto a loading device and driven by the loading device to move in the coating chamber along the length direction of the coating chamber by means of at least one discharge coil arranged to a coating chamber of a coating apparatus, wherein the discharge coil is conductively connected to a radio frequency power supply; and
forming a coating on a surface of the substrate.

16. The coating method according to claim 15, wherein the number of the discharge coil is at least two, and at least one of the discharge coils is configured to cooperate with the other discharge coil in operation, so that the coating chamber provides a uniform plasma environment around the substrate.

17. The coating method according to claim 15, wherein the discharge coil surrounds a motion trajectory of the substrate.

18. The coating method according to claim 15, wherein the substrate is placed on a bracket, at least a part of the bracket is conductively connected to an impulsing power source, and coating is conducted under the combined action of the radio frequency power supply and the impulsing power source.

19. The coating method according to claim 15, wherein the substrate is placed on a bracket, and the bracket is provided to be rotatable to drive the substrate to rotate in the coating chamber, so that the plasma distributes evenly in the coating chamber.
